(19) United States
(12) Patent Application Publication
(10) Pub. No.: US 2025/0168980 A1
(43) Pub. Date: May 22, 2025

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Min Gyu PARK, Suwon-si (KR); Jin Uk LEE, Suwon-si (KR); Kee Ju UM, Suwon-si (KR)

(73) Assignee: SAMSUNG ELECTRO-MECHANICS CO., LTD., Suwon-si (KR)

(21) Appl. No.: 18/663,279

(22) Filed: May 14, 2024

(30) Foreign Application Priority Data
Nov. 20, 2023 (KR) 10-2023-0161126

(51) Int. Cl. H05K 1/11; H05K 3/42

(52) U.S. Cl. CPC H05K 1/115; H05K 3/423; H05K 2201/09827; H05K 2203/0723; H05K 2203/1131

(57) ABSTRACT

A printed circuit board includes an insulating layer, a through-hole including a first region penetrating through a portion of the insulating layer from an upper surface of the insulating layer and a second region penetrating through another portion of the insulating layer from a lower surface of the insulating layer, and a metal via including a first metal layer disposed in a portion of the first region, a second metal layer disposed above the first metal layer and disposed in another portion of the first region, and a third metal layer disposed below the first metal layer and disposed in the second region. An upper surface of the first metal layer is located below the upper surface of the insulating layer.

### CROSS-REFERENCE TO RELATED APPLICATION(S)

This application claims benefit of priority to Korean Patent Application No. 10-2023-0161126 filed on Nov. 20, 2023 in the Korean Intellectual Property Office, the disclosure of which is incorporated herein by reference in its entirety.

### TECHNICAL FIELD

The present disclosure relates to a printed circuit board and a method of manufacturing the same.

Package technology has been continuously developed, and in particular, attempts to use silicon or glass in traditional substrate manufacturing methods, away from organic materials, has continued. As is known, glass has better warpage characteristics and better flatness than existing organic materials, which may be advantageous in reducing trace lines and spaces. However, currently, it may be difficult to form a metal via in a thick glass substrate, when manufacturing a glass substrate. For example, although a seed layer is required to proceed with plating within a through-hole, since a glass surface is smooth and through-holes generally have a high aspect ratio, seed formation may be difficult. In addition, in the case of forming seeds through a sputtering process, or the like, a lot of time and costs may be required to form seeds having a desired thickness. In addition, significant voids may occur during a fill plating process of through-holes.

### SUMMARY

An aspect of the present disclosure is to provide a printed circuit board in which voids are minimized even when fill plating is performed on a through-hole formed in a glass substrate or the like, thereby improving quality of the substrate, and a method of manufacturing the same.

An aspect of the present disclosure is to provide a printed circuit board in which a seed forming process is omitted even when fill plating is performed on a through-hole formed in a glass substrate or the like, thereby minimizing time and costs, and a method of manufacturing the same.

According to an aspect of the present disclosure, a printed circuit board includes: an insulating layer; a through-hole including a first region penetrating through a portion of the insulating layer from an upper surface of the insulating layer and a second region penetrating through another portion of the insulating layer from a lower surface of the insulating layer; and a metal via including a first metal layer disposed in a portion of the first region, a second metal layer disposed above the first metal layer and disposed in another portion of the first region, and a third metal layer disposed below the first metal layer and disposed in the second region. An upper surface of the first metal layer is located below the upper surface of the insulating layer.

According to another aspect of the present disclosure, a method of manufacturing a printed circuit board includes: forming a first through-hole in the insulating layer to penetrate through a portion of an insulating layer from an upper surface of the insulating layer; forming a first metal layer filling a portion of the first through-hole; forming a second through-hole in the insulating layer to penetrate through another portion of the insulating layer from a lower surface of the insulating layer and exposing a lower side of the first metal layer; and forming second and third metal layers filling the first and second through-holes, respectively, on the upper and lower sides of the first metal layer.

According to an aspect of the present disclosure, a printed circuit board includes: an insulating layer; a through-hole including a first region penetrating through a portion of the insulating layer from an upper surface of the insulating layer and a second region penetrating through another portion of the insulating layer from a lower surface of the insulating layer to connect to the first region; and a metal via including a first metal layer disposed in a portion of the first region and a third metal layer disposed below the first metal layer and disposed in the second region. In a cross-section, walls of the first region and the second region are inclined in different directions or have a step therebetween.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a cross-sectional view schematically illustrating a modified example of the printed circuit board of FIG. 3;

FIGS. 5A to 5F are cross-sectional views schematically illustrating an example of manufacturing the printed circuit board of FIG. 3 and the printed circuit board of FIG. 4;

FIG. 6 is a cross-sectional view schematically illustrating another example of a printed circuit board;

FIG. 7 is a cross-sectional view schematically illustrating a modified example of the printed circuit board of FIG. 6;

FIGS. 8A to 8F are cross-sectional views schematically illustrating an example of manufacturing the printed circuit board of FIG. 6 and the printed circuit board of FIG. 7;

FIG. 9 is a cross-sectional view schematically illustrating another example of a printed circuit board;

FIG. 10 is a cross-sectional view schematically illustrating a modified example of the printed circuit board of FIG. 9;

FIGS. 11A to 11F are cross-sectional views schematically illustrating an example of manufacturing the printed circuit board of FIG. 9 and the printed circuit board of FIG. 10;

FIG. 12 is a cross-sectional view schematically illustrating another example of a printed circuit board;

FIG. 13 is a cross-sectional view schematically illustrating a modified example of the printed circuit board of FIG. 12;

FIG. 14 is a cross-sectional view schematically illustrating another example of a printed circuit board;

FIG. 15 is a cross-sectional view schematically illustrating a modified example of the printed circuit board of FIG. 14;

FIG. 16 is a cross-sectional view schematically illustrating another example of a printed circuit board;

FIG. 17 is a cross-sectional view schematically illustrating a modified example of the printed circuit board of FIG. 16;

FIG. 18 is a cross-sectional view schematically illustrating another example of a printed circuit board;

FIG. 19 is a cross-sectional view schematically illustrating a modified example of the printed circuit board of FIG. 18;

FIG. 20 is a cross-sectional view schematically illustrating another example of a printed circuit board;

FIG. 21 is a cross-sectional view schematically illustrating a modified example of the printed circuit board of FIG. 20;

FIG. 22 is a cross-sectional view schematically illustrating another example of a printed circuit board; and

FIG. 23 is a cross-sectional view schematically illustrating a modified example of the printed circuit board of FIG. 22.

### DETAILED DESCRIPTION

Hereinafter, the present disclosure are described with reference to the accompanying drawings. The shapes and sizes of elements in the drawings may be exaggerated or reduced for clarity.

### Electronics

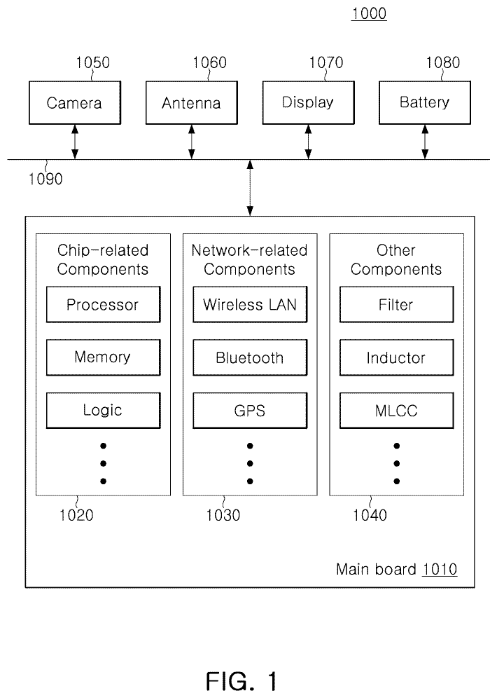

FIG. 1 is a block diagram schematically illustrating an example of an electronic device system.

Referring to FIG. 1, an electronic device 1000 accommodates a main board 1010. Chip-related components 1020, network-related components 1030, other components 1040, and the like are physically and/or electrically connected to the main board 1010. These components may also be coupled with other electronic components described below to form various signal lines 1090.

The chip-related components 1020 include memory chips, such as volatile memory (e.g., DRAM), non-volatile memory (e.g., ROM), and flash memory; application processor chips, such as central processing units (CPUs), graphics processing units (GPUs), digital signal processors, cryptographic processors, microprocessors, and microcontrollers; logic chips, such as analog-to-digital converters (ADCs) and application-specific IC (ASICs), but without being limited thereto, the chip-related components 1020 may include other types of chip-related components. In addition, these chip-related components 1020 may be combined with each other. The chip-related components 1020 may be provided as a package including the aforementioned chips or electronic components.

The network-related components 1030 include Wi-Fi (IEEE 802.11 family, and the like), WiMAX (IEEE 802.16 family, and the like), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, 5G and any other wireless and wired protocols designated afterwards, but without being limited thereto, the network-related components 1030 may include some of many other wireless or wired standards or protocols. In addition, the network-related components 1030 may be combined with the chip-related components 1020.

The other components 1040 include high-frequency inductors, ferrite inductors, power inductors, ferrite beads, low temperature co-fired ceramics (LTCC), electromagnetic interference (EMI) filters, multilayer ceramic capacitors (MLCCs), and the like. However, without being limited thereto, the other components 1040 may include passive elements in the form of chip components used for various other purposes. In addition, the other components 1040 may be combined with the chip-related components 1020 and/or the network-related components 1030.

Depending on the type of electronic device 1000, the electronic device 1000 may include other electronic components that may or may not be physically and/or electrically connected to the main board 1010. Examples of the other electronic components include a camera module 1050, an antenna module 1060, a display 1070, and a battery 1080. However, without being limited thereto, the other electric components may include an audio codec, a video codec, a power amplifier, a compass, an accelerometer, a gyroscope, a speaker, a mass storage device (e.g., a hard disk drive), a compact disk (CD), a digital versatile disk (DVD), and the like. In addition to this, other electronic components used for various purposes may be included depending on the type of electronic device 1000.

The electronic device 1000 may include a smartphone, a personal digital assistant, a digital video camera, a digital still camera, a network system, a computer, a monitor, a tablet, a laptop, a netbook, a television, a video game, a smart watch, an automotive, and the like. However, without being limited thereto, the electronic device 1000 may be any other electronic device processing data.

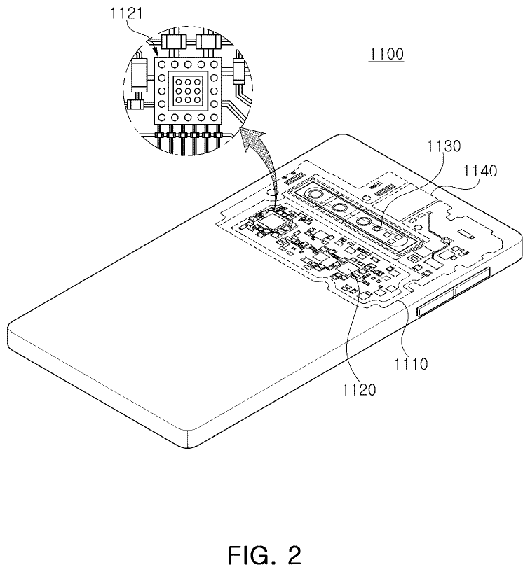

FIG. 2 is a perspective view schematically illustrating an example of an electronic device.

Referring to FIG. 2, the electronic device may be, for example, a smartphone 1100. A motherboard 1110 is accommodated inside the smartphone 1100, and various components 1120 are physically and/or electrically connected to the motherboard 1110. In addition, other components, such as the camera module 1130 and/or the speaker 1140, that may or may not be physically and/or electrically connected to the motherboard 1110 are accommodated in the motherboard 1110. Some of the components 1120 may be the chip-related components described above, for example, a component package 1121, but are not limited thereto. The component package 1121 may be in the form of a printed circuit board on which electronic components including active components and/or passive components are surface-mounted. Alternatively, the component package 1121 may be in the form of a printed circuit board with built-in active components and/or passive components. Meanwhile, the electronic device is not limited to the smartphone 1100 and may be other electronic devices as described above.

### Printed Circuit Board (PCB)

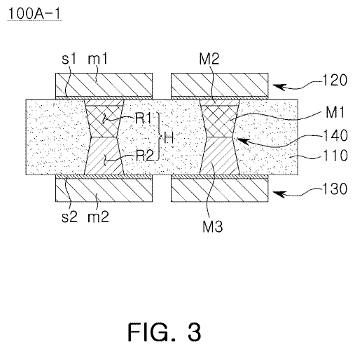

FIG. 3 is a cross-sectional view schematically illustrating an example of a printed circuit board.

Referring to FIG. 3, a PCB 100A-1 according to an example may include an insulating layer 110, a first metal interconnection 120 disposed on an upper surface of the insulating layer 110, a second metal interconnection 130 disposed on a lower surface of the insulating layer 110, and a metal via 140 connecting the first and second metal interconnections 120 and 130 to each other through the insulating layer 110. The insulating layer 110 may include a through-hole H having a first region R1 penetrating through a portion of the insulating layer 110 from the upper surface of the insulating layer 110 and a second region R2 penetrating through another portion of the insulating layer 110 from the lower surface of the insulating layer 110. The metal via 140 may include a first metal layer M1 filling a portion of the first region R1, a second metal layer M2 disposed on an upper side of the first metal layer M1 and filling another portion of the first region R1, and a third metal layer M3 disposed below the first metal layer M1 and filling the second region R2. An upper surface of the first metal layer M1 may be located below the upper surface of the insulating layer 110. The first and second regions R1 and R2 of the through-hole H may respectively correspond to first and second through-holes h1 and h2 in a manufacturing method described below.

As such, in the PCB 100A-1 according to an example, in the insulating layer 110 having a significant thickness, such as a glass substrate, the first region R1 may be first formed, the first metal layer M1 may be formed by filling a portion of the first region R1 with conductive paste and sintering the conductive paste, and then, after the second region R2 is formed, the second and third metal layers M2 and M3 may be formed to fill the remainder of the first and second regions R1 and R2 by electroplating or the like using the first metal layer M1 as a seed to form the metal via 140 passing through the insulating layer 110 and having a high aspect ratio. Therefore, the occurrence of voids in the through-hole H may be effectively suppressed. In addition, a seed forming process for fill plating, such as a sputtering process, may be omitted.

Meanwhile, the first metal layer M1 may have a boundary with each of the second and third metal layers M2 and M3. For example, the first metal layer M1 may have a different metal crystal structure from each of the second and third metal layers M2 and M3. For example, the first metal layer M1 may be formed by filling and sintering with conductive paste, and the second and third metal layers M2 and M3 may be formed by electroplating. An interface between the first and third metal layers M1 and M3 may be substantially the same as an interface between the first and second regions R1 and R2. For example, the first and second regions R1 and R2 may be arranged so that at least portions thereof overlap each other on a plane and are connected to each other based on a thickness direction. At this time, the first metal layer M1 may fill a lower side of the first region R1 but not the second region R2, and the third metal layer M3 may be in contact with the metal layer M1 exposed from the second region R2. In this case, a boundary between the first and third metal layers M1 and M3 may be at a level corresponding to (e.g., the same as) a level of an interface between the first and second regions R1 and R2. These structural features may be a basic structure to achieve the aforementioned effects.

Meanwhile, the first region R1 may have a tapered shape in which a width of an upper end is greater than a width of a lower end in cross-section. In addition, the second region R2 may have a tapered shape in which a width of a lower end is greater than a width of an upper end in cross-section. For example, the through-hole H may have an hourglass shape in cross-section. For example, the first and second regions R1 and R2 may have substantially the same depth in cross-section. In this case, in a cross-section, walls of the first region R1 and the second region R2 may be inclined in different directions. In addition, the width of the lower end of the first region R1 in cross-section and the width of the upper end of the second region R2 in cross-section may be substantially equal to each other. In addition, the first and second regions R1 and R2 may have substantially the same area in cross-section. These structural features may be a basic structure to achieve the aforementioned effects.

Meanwhile, the upper surface of the insulating layer 110 may be substantially coplanar with the upper surface of the second metal layer M2. In addition, the lower surface of the insulating layer 110 may be substantially coplanar with the lower surface of the third metal layer M3. For example, after electroplating to form the second and third metal layers M2 and M3, a planarization process, such as a polishing process, may be performed. Accordingly, the first and second metal interconnections 120 and 130 may be easily formed on a flat surface by plating. For example, the first metal interconnection 120 may include a first seed metal layer s1 disposed on the upper surface of the insulating layer 110 and the upper surface of the second metal layer M2 and a first interconnection metal layer m1 disposed on an upper surface of the first seed metal layer s1 and having a greater thickness than that of the first seed metal layer s1. In addition, the second metal interconnection 130 may include a second seed metal layer s2 disposed on the lower surface of the insulating layer 110 and the lower surface of the metal layer M2 and a second interconnection metal layer m2 disposed on a lower surface of the second seed metal layer s2 and having a thickness greater than that of the second seed metal layer s2. In this case, it may be easier to manufacture a package substrate, or the like by performing an additional build-up process.

Meanwhile, the PCB 100A-1 according to an example may be applied as any one layer of a multilayer circuit board. For example, the PCB 100A-1 may be applied as a core layer of a multilayer circuit board, and in this case, a build-up process may be performed on one or both sides of the PCB 100A-1. The multilayer circuit board may be used as a flip-chip board (FCB), a ball grid array (BGA), an interposer substrate, a package substrate, and the like. However, without being limited thereto and the PCB 100A-1 may be applied to various other types of substrates.

Hereinafter, the components of the PCB 100A-1 according to an example are described in more detail with reference to the drawings.

The insulating layer 110 may include a glass substrate. The glass substrate may include glass, which is an amorphous solid. Glass may include, for example, pure silicon dioxide (about 100% SiO₂), soda lime glass, borosilicate glass, alumino-silicate glass, and the like. However, without being limited thereto, alternative glass materials, such as fluorine glass, phosphate glass, chalcogen glass, and the like may also be used as materials. In addition, other additives may be further included to form glass having specific physical properties. These additives may include calcium carbonate (e.g. lime) and sodium carbonate (e.g. soda), as well as magnesium, calcium, manganese, aluminum, lead, boron, iron, chromium, potassium, sulfur, and antimony, and carbonates and/or oxides of the listed elements and other elements. The glass substrate may be distinguished from organic insulating materials including glass fiber, glass cloth, and glass fabric, such as a copper clad laminate (CCL) and prepreg (PPG). For example, the glass substrate may include plate glass. However, the insulating layer 110 is not limited to a glass substrate, and substrates formed of various materials that are difficult to perform fill plating on through-holes due to voids or the like using related art methods may be applied as the insulating layer 111. For example, a silicon substrate, a ceramic substrate, and the like may be applied as the insulating layer 110, and if necessary, an organic substrate may also be applied as the insulating layer 110.

The first and second metal interconnections 120 and 130 may each include metal. The metal may include copper (Cu), aluminum (Al), silver (Ag), tin (Sn), gold (Au), nickel (Ni), lead (Pb), titanium (Ti), and/or alloys thereof. For example, the first and second seed metal layers s1 and s2 and the first and second interconnection metal layers m1 and m2 of the first and second metal interconnections 120 and 130 may each include the metal described above, and preferably, include copper (Cu), but are not limited thereto. The first and second metal interconnections 120 and 130 may each perform various functions depending on their design. For example, the first and second metal interconnections 120 and 130 may include signal patterns, power patterns, ground patterns, and the like. Each of these patterns may have various forms, such as lines, planes, and pads. The first and second metal interconnections 120 and 130 may include an electroless plating layer (or chemical copper) and an electrolytic plating layer (or electrical copper), respectively. The first and second metal interconnections 120 and 130 may include a sputtering layer, instead of an electroless plating layer (or chemical copper), and may include both an electroless plating layer (or chemical copper) and a sputtering layer, if necessary.

The metal via 140 may include metal. The metal may include copper (Cu), aluminum (Al), silver (Ag), tin (Sn), gold (Au), nickel (Ni), lead (Pb), titanium (Ti), and/or alloys thereof. For example, the first to third metal layers M1, M2, and M3 of the metal via 140 may each include the metals described above. For example, the first metal layer M1 may include copper (Cu) coated with silver (Ag), and the second and third metal layers M2 and M3 may each include copper (Cu), but are not limited thereto. The metal via 140 may perform various functions depending on the design. For example, the metal via 140 may include ground vias, power vias, signal vias, and the like. The metal via 140 may include a sintered layer of conductive paste and an electrolytic plating layer. The electrolytic plating layer may be a fill plating layer.

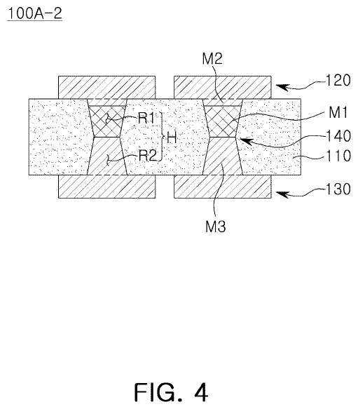

FIG. 4 is a cross-sectional view schematically illustrating a modified example of the PCB of FIG. 3.

Referring to FIG. 4, in a PCB 100A-2 according to the modified example, the second metal layer M2 may extend to be disposed on the upper surface of the insulating layer 110 and the third metal layer M3 may extend to be disposed on the lower surface of the insulating layer 110 in the PCB 100A-1 according to the aforementioned example. At this time, the first metal interconnection 120 may include the extended second metal layer M2, and the second metal interconnection 130 may include the extended third metal layer M3. For example, at least a portion of each of the first and second metal interconnections 120 and 130 may be integrated with the metal via 140. As such, in the PCB 100A-2 according to the modified example, the first and second seed metal layers s1 and s2 and the first and second interconnection metal layers m1 and m2 may be omitted, and the first and second metal interconnections 120 and 130 may be formed by polishing the second and third metal layers M2 and M3 in a pattern having a thickness required for design during a polishing process of the second and third metal layers M2 and M3. Therefore, when applied together with a glass substrate, the PCB 100A-2 may be easily applied to a packaging board having low loss characteristics of high-frequency signals by utilizing the characteristics of the glass substrate.

Descriptions of other parts may be substantially the same as those of the PCB 100A-1 according to the aforementioned example, and therefore, redundant descriptions are omitted.

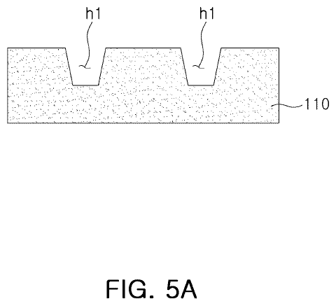

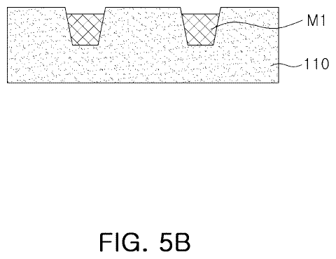

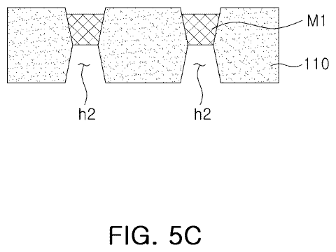

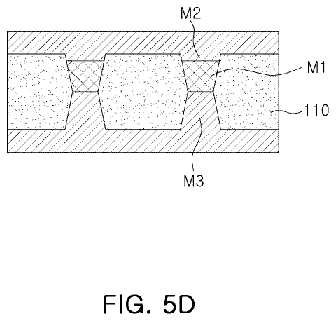

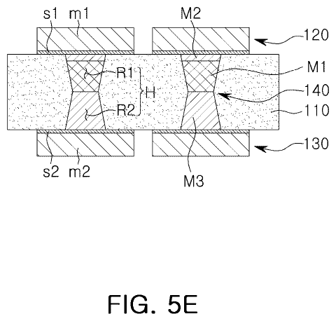

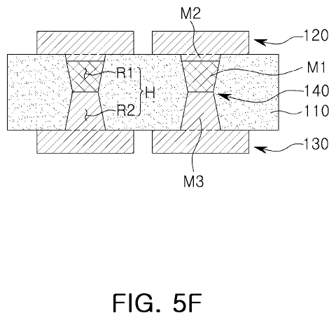

FIGS. 5A to 5F are cross-sectional views schematically illustrating an example of manufacturing the PCB of FIG. 3 and the PCB of FIG. 4.

Referring to FIG. 5A, the insulating layer 110 may be prepared. As described above, the insulating layer 110 may be a glass substrate, such as plate glass. Next, the first through-hole h1 penetrating through a portion of the insulating layer 110 from the upper surface of the insulating layer 110 may be formed. The first through-hole h1 may be formed by a chemical method or a mechanical method depending on the material of the insulating layer 110. For example, and the etching, blast, laser, plasma, and the like may be used.

Referring to FIG. 5B, the first metal layer M1 may be formed to fill a portion of the first through-hole h1. The first metal layer M1 may be formed by filling a portion of the first through-hole h1 with conductive paste and then performing sintering thereon. The conductive paste may include copper (Cu), and may also include a binder resin and a solvent. For example, the conductive paste may be a low-temperature sintering material, such as Ag coated copper paste (ACCP). The first metal layer M1 may be formed so that the upper surface thereof is located below the upper surface of the insulating layer 110.

Referring to FIG. 5C, the second through-hole h2 may be formed to penetrate through another portion of the insulating layer 110 from the lower surface of the insulating layer 110 and exposing a lower side of the first metal layer M1. The second through-hole h2 may also be formed by a chemical or mechanical method, such as and the etching, blasting, laser, or plasma, depending on the material of the insulating layer 110.

Referring to FIG. 5D, the second and third metal layers M2 and M3 may be formed on the upper and lower sides of the first metal layer M1 to fill the first and second through-holes h1 and h2, respectively. The second and third metal layers M2 and M3 may be formed by electroplating, for example, copper electroplating, using the first metal layer M1 as a seed layer. At this time, the electroplating conditions may be set to minimize voids, and thus the occurrence of voids during the fill plating process by electroplating may be minimized. In addition, a separate sputtering process, and the like may be omitted.

Referring to FIG. 5E, after electroplating, the upper and lower surfaces of the insulating layer 110 and the respective plating surfaces of the second and third metal layers M2 and M3 may be planarized to be substantially on the same level through a polishing process, such as chemical mechanical planarization (CMP). Through this, the metal via 140 may be formed. Next, electroless plating and electrolytic plating may be performed on the upper and lower surfaces of the insulating layer 110 and the upper and lower surfaces of the second and third metal layers M2 and M3. Through this, the first and second metal interconnections 120 and 130 respectively including the first and second seed metal layers s1 and s2 and first and second interconnection metal layers m1 and m2 and connected to each other through the metal via 140 may be formed. The PCB 100A-1 according to an example may be manufactured through the sequential processes, and a build-up process may be further performed if necessary.

Referring to FIG. 5F, after electroplating, the second and third metal layers M2 and M3 may be polished to a pattern having a thickness required for the design by a polishing process, such as CMP and then patterned by chemical etching or the like. Through this, first and second metal interconnections 120 and 130 respectively including the second and third metal layers M2 and M3 and connected to each other through the metal via 140 may be formed. The PCB 100A-2 according to the modified example may be manufactured through the sequential processes, and a build-up process may be further performed if necessary.

Descriptions of other parts may be substantially the same as those of the PCB 100A-1 according to the aforementioned example and the PCB 100A-2 according to the modified example, and therefore, redundant descriptions are omitted.

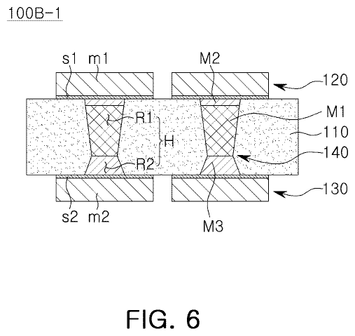

FIG. 6 is a cross-sectional view schematically illustrating another example of a PCB.

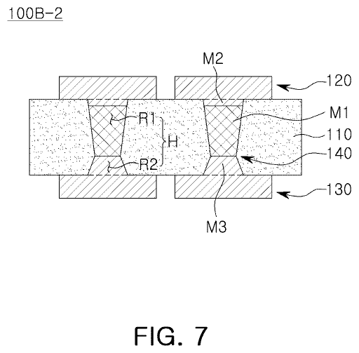

FIG. 7 is a cross-sectional view schematically illustrating a modified example of the PCB of FIG. 6.

Referring to FIGS. 6 and 7, in a PCB 100B-1 according to another example and a PCB 100B-2 according to the modified example thereof, the first region R1 may be deeper than the second region R2 in the PCB 100A-1 according to the aforementioned example and the PCB 100A-2 according to the modified example thereof. For example, in cross-section, the area of the first region R1 may be larger than the area of the second region R2. In this case, the first metal layer M1 may be formed larger, and the occurrence of voids during the electroplating process for forming the second and third metal layers M2 and M3 may be more effectively improved.

Descriptions of other parts may be substantially the same as those of the PCB 100A-1 according to the aforementioned example and the PCB 100A-2 according to the modified example, and therefore, redundant descriptions are omitted.

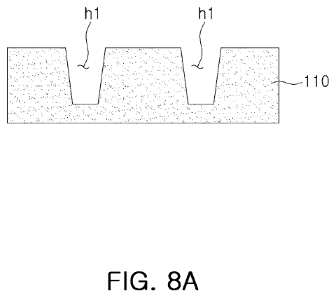

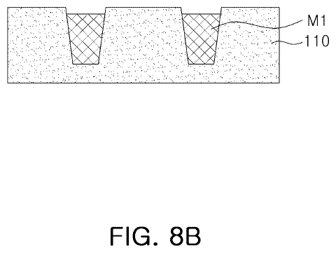

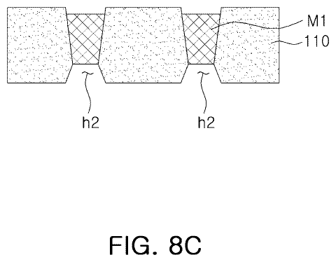

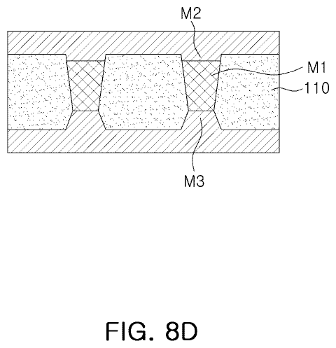

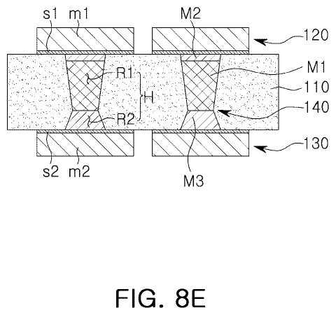

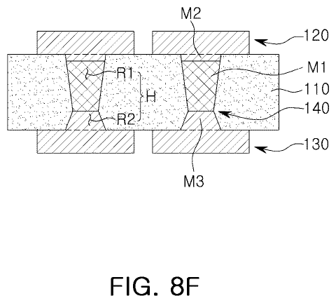

FIGS. 8A to 8F are cross-sectional views schematically illustrating an example of manufacturing the PCB of FIG. 6 and the PCB of FIG. 7.

Referring to FIGS. 8A to 8F, in an example of manufacturing the PCB 100B-1 according to another example and the PCB 100B-2 according to a modified example thereof, the first through-hole h1 may be formed deeper than the second through-hole h2 in the example of manufacturing the PCB 100A-1 according to the aforementioned example and the PCB 100A-2 according to the modified example. In this case, the first metal layer M1 may be formed larger, and the occurrence of voids during the electroplating process for forming the second and third metal layers M2 and M3 may be more effectively improved.

Descriptions of other parts may be substantially the same as those of the PCB 100A-1 according to the aforementioned example, the PCB 100A-2 according to the modified example, and the examples of manufacturing the same, and therefore, redundant descriptions are omitted.

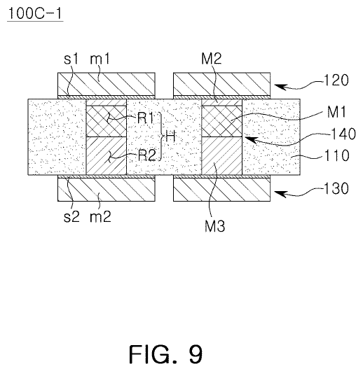

FIG. 9 is a cross-sectional view schematically illustrating another example of a PCB.

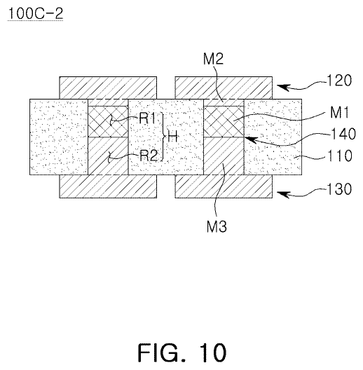

FIG. 10 is a cross-sectional view schematically illustrating a modified example of the PCB of FIG. 9.

Referring to FIGS. 9 and 10, in a PCB 100C-1 according to another example and a PCB 100C-2 according to a modified example thereof, the first region R1 may have a rectangular shape with a wall substantially vertical in cross-section and the second region R2 may have a wall substantially vertical in cross-section in the PCB 100A-1 according to the aforementioned example and the PCB 100A-2 according to the modified example thereof. For example, the metal via 140 may have a pillar shape in cross-section. In this case, the area of the metal via 140 may be expanded and electrical conduction may be improved.

Descriptions of other parts may be substantially the same as those of the PCB 100A-1 according to the aforementioned example and the PCB 100A-2 according to the modified example, and therefore, redundant descriptions are omitted.

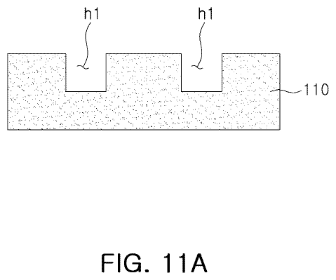

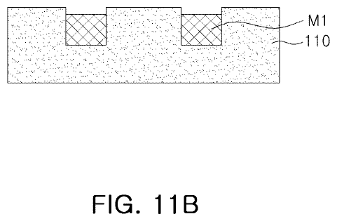

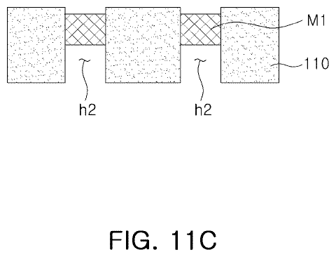

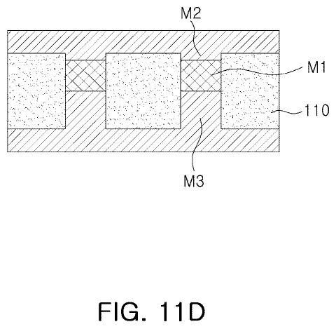

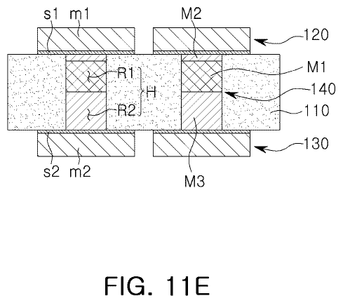

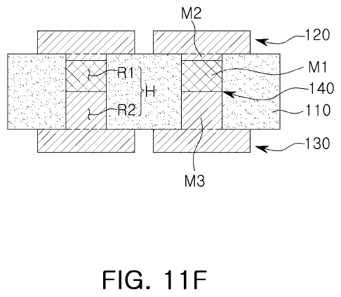

FIGS. 11A to 11F are cross-sectional views schematically illustrating an example of manufacturing the PCB of FIG. 9 and the PCB of FIG. 10.

Referring to FIGS. 11A to 11f, in the example of manufacturing of the PCB 100C-1 according to another example and the PCB 100C-2 according to the modified example thereof, the first through-hole h1 and the second through-hole h2 are each formed in a square shape or a rectangular shape with walls substantially vertical in cross-section, in the example of manufacturing of the PCB 100A-1 according to the aforementioned example and the PCB 100A-2 according to the modified example thereof. For example, the metal via 140 may be formed in a pillar shape in cross-section. In this case, the area of the metal via 140 may be expanded and electrical conduction may be improved.

Descriptions of other parts may be substantially the same as those of the PCB 100A-1 according to the aforementioned example, the PCB 100A-2 according to the modified example, and the examples of manufacturing the same, and therefore, redundant descriptions are omitted.

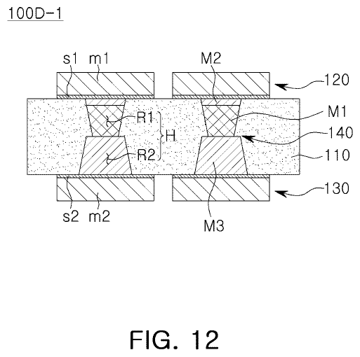

FIG. 12 is a cross-sectional view schematically illustrating another example of a PCB.

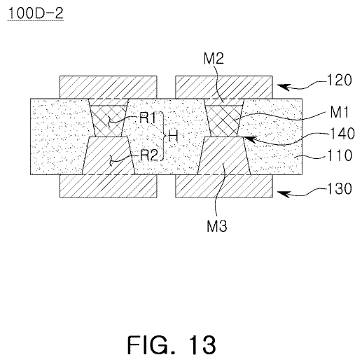

FIG. 13 is a cross-sectional view schematically illustrating a modified example of the PCB of FIG. 12.

Referring to FIGS. 12 and 13, in a PCB 100D-1 according to another example and a PCB 100D-2 according to a modified example thereof, a width of the lower end in of the first region R1 the cross-section may be different from a width of the upper end of the second region R2 in cross-section in the PCB 100A-1 according to the aforementioned example and the PCB 100A-2 according to the modified example thereof. For example, the width of the upper end of the second region R2 in cross-section may be greater than that of the lower end of the first region R1 in cross-section. In this case, in a cross-section, walls of the first region R1 and the second region R2 may have a step therebetween. In this manner, the first and second regions R1 and R2 may be formed in various shapes and the degree of design freedom may be high.

Descriptions of other parts may be substantially the same as those of the PCB 100A-1 according to the aforementioned example and the PCB 100A-2 according to the modified example, and therefore, redundant descriptions are omitted.

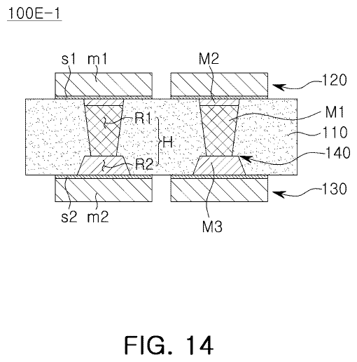

FIG. 14 is a cross-sectional view schematically illustrating another example of a PCB.

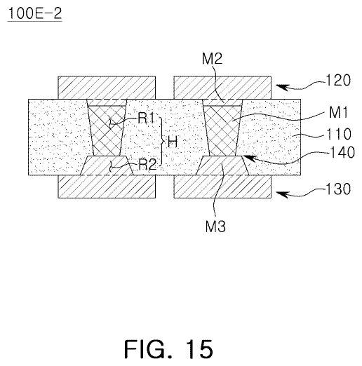

FIG. 15 is a cross-sectional view schematically illustrating a modified example of the PCB of FIG. 14.

Referring to FIGS. 14 and 15, in a PCB 100E-1 according to another example and a PCB 100E-2 according to a modified example thereof, a width of the lower end in of the first region R1 the cross-section may be different from a width of the upper end of the second region R2 in cross-section in the PCB 100B-1 according to the aforementioned example and the PCB 100B-2 according to the modified example thereof. For example, the width of the upper end of the second region R2 in cross-section may be greater than that of the lower end of the first region R1 in cross-section. In this case, in a cross-section, walls of the first region R1 and the second region R2 may have a step therebetween. In this manner, the first and second regions R1 and R2 may be formed in various shapes and the degree of design freedom may be high.

Descriptions of other parts may be substantially the same as those of the PCB 100A-1 according to the aforementioned example, the PCB 100A-2 according to the modified example, the PCB 100B-1 according to the aforementioned example, and the PCB 100B-2 according to the modified example, and therefore, redundant descriptions are omitted.

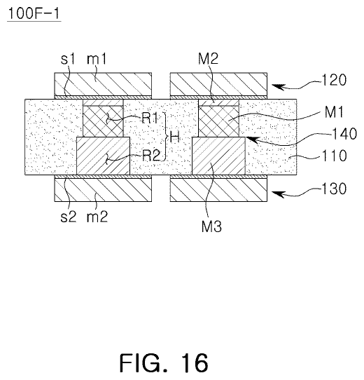

FIG. 16 is a cross-sectional view schematically illustrating another example of a PCB.

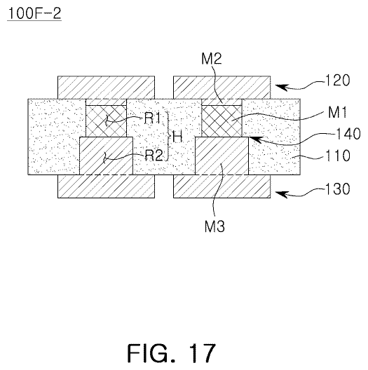

FIG. 17 is a cross-sectional view schematically illustrating a modified example of the PCB of FIG. 16.

Referring to FIGS. 16 and 17, in a PCB 100F-1 according to another example and a PCB 100F-2 according to a modified example thereof, a width of the lower end in of the first region R1 the cross-section may be different from a width of the upper end of the second region R2 in cross-section in the PCB 100C-1 according to the aforementioned example and the PCB 100C-2 according to the modified example thereof. For example, the width of the upper end of the second region R2 in cross-section may be greater than that of the lower end of the first region R1 in cross-section. In this case, in a cross-section, walls of the first region R1 and the second region R2 may have a step therebetween. In this manner, the first and second regions R1 and R2 may be formed in various shapes and the degree of design freedom may be high.

Descriptions of other parts may be substantially the same as those of the PCB 100A-1 according to the aforementioned example, the PCB 100A-2 according to the modified example, the PCB 100C-1 according to the aforementioned example, and the PCB 100C-2 according to the modified example, and therefore, redundant descriptions are omitted.

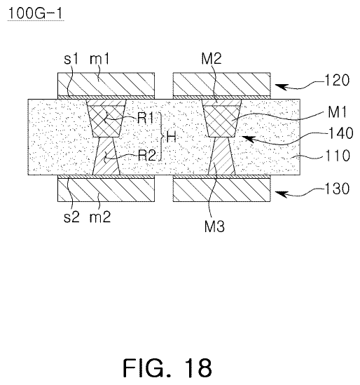

FIG. 18 is a cross-sectional view schematically illustrating another example of a PCB.

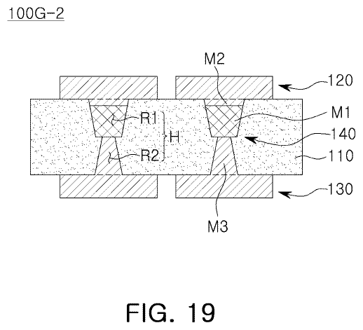

FIG. 19 is a cross-sectional view schematically illustrating a modified example of the PCB of FIG. 18.

Referring to FIGS. 18 and 19, in a PCB 100G-1 according to another example and a PCB 100G-2 according to a modified example thereof, a width of the lower end in of the first region R1 the cross-section may be different from a width of the upper end of the second region R2 in cross-section in the PCB 100A-1 according to the aforementioned example and the PCB 100A-2 according to the modified example thereof. For example, the width of the upper end of the second region R2 in cross-section may be less than that of the lower end of the first region R1 in cross-section. In this case, in a cross-section, walls of the first region R1 and the second region R2 may have a step therebetween. In this manner, the first and second regions R1 and R2 may be formed in various shapes and the degree of design freedom may be high.

Descriptions of other parts may be substantially the same as those of the PCB 100A-1 according to the aforementioned example and the PCB 100A-2 according to the modified example, and therefore, redundant descriptions are omitted.

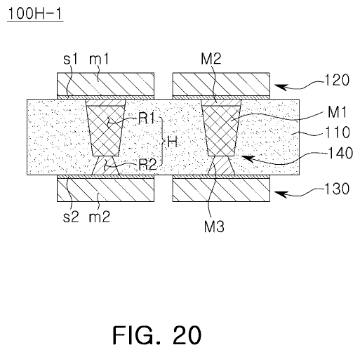

FIG. 20 is a cross-sectional view schematically illustrating another example of a PCB.

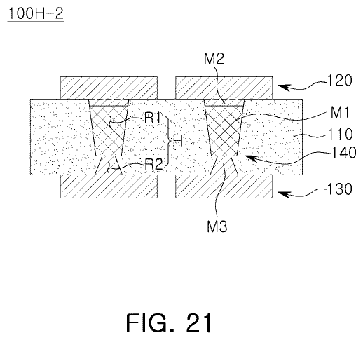

FIG. 21 is a cross-sectional view schematically illustrating a modified example of the PCB of FIG. 20.

Referring to FIGS. 20 and 21, in a PCB 100H-1 according to another example and a PCB 100H-2 according to a modified example thereof, a width of the lower end in of the first region R1 the cross-section may be different from a width of the upper end of the second region R2 in cross-section in the PCB 100B-1 according to the aforementioned example and the PCB 100B-2 according to the modified example thereof. For example, the width of the upper end of the second region R2 in cross-section may be less than that of the lower end of the first region R1 in cross-section. In this case, in a cross-section, walls of the first region R1 and the second region R2 may have a step therebetween. In this manner, the first and second regions R1 and R2 may be formed in various shapes and the degree of design freedom may be high.

Descriptions of other parts may be substantially the same as those of the PCB 100A-1 according to the aforementioned example, the PCB 100A-2 according to the modified example, the PCB 100B-1 according to the aforementioned example, and the PCB 100B-2 according to the modified example, and therefore, redundant descriptions are omitted.

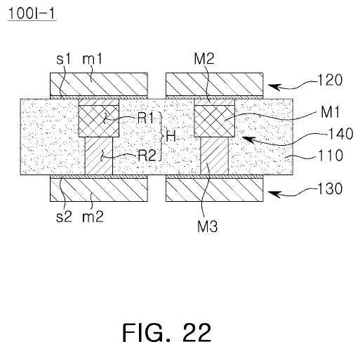

FIG. 22 is a cross-sectional view schematically illustrating another example of a PCB.

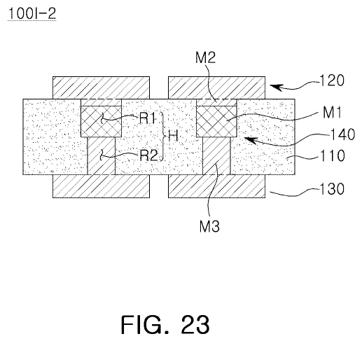

FIG. 23 is a cross-sectional view schematically illustrating a modified example of the PCB of FIG. 22.

Referring to FIGS. 22 and 23, in a PCB 100I-1 according to another example and a PCB 100I-2 according to a modified example thereof, a width of the lower end in of the first region R1 the cross-section may be different from a width of the upper end of the second region R2 in cross-section in the PCB 100C-1 according to the aforementioned example and the PCB 100C-2 according to the modified example thereof. For example, the width of the upper end of the second region R2 in cross-section may be less than that of the lower end of the first region R1 in cross-section. In this case, in a cross-section, walls of the first region R1 and the second region R2 may have a step therebetween. In this manner, the first and second regions R1 and R2 may be formed in various shapes and the degree of design freedom may be high.

Descriptions of other parts may be substantially the same as those of the PCB 100A-1 according to the aforementioned example, the PCB 100A-2 according to the modified example, the PCB 100C-1 according to the aforementioned example, and the PCB 100C-2 according to the modified example, and therefore, redundant descriptions are omitted.

As one of the various effects of the present disclosure, the PCB in which voids are minimized even when fill plating is performed on a through-hole formed in a glass substrate or the like, thereby improving quality of the substrate, and the method of manufacturing the same may be provided.

The PCB in which a seed forming process is omitted even when fill plating is performed on a through-hole formed in a glass substrate or the like, thereby minimizing time and costs, and the method of manufacturing the same may be provided.

In the present disclosure, the expression “covering” may include not only covering entirely but also covering at least portion, and may also include covering indirectly as well as covering directly. In addition, the expression “filling” may include not only completely filling but also at least partially filling, and may also include approximately filling. For example, this may include cases in which some air gaps or voids exist. In addition, the expression “surrounding” may include not only completely surrounding, but also partially surrounding and approximately surrounding. In addition, the expression “being adjacent to” refers to arrangement next to each other on substantially the same layer and is not limited to a case of being in contact with each other. In addition, exposing may include not only fully exposing but also partially exposing, and exposing may refer to exposing from burying a corresponding component.

In the present disclosure, determination may be made to include process errors, position deviations, errors during measurement, and the like that occur during a manufacturing process. For example, substantially being coplanar may include not only presence completely on the same plane, but also presence approximately on the same plane.

In the present disclosure, cross-section may refer to a cross-sectional shape when an object is cut vertically, a cross-sectional shape when an object is cut vertically, or a cross-sectional shape when an object is viewed from a side view. In addition, “on a plane” may refer to a planar shape when an object is cut horizontally or a planar shape when an object is viewed from a top-view or bottom-view.

In the present disclosure, a lower side, a lower portion, a lower surface, and the like are used to refer to a downward direction based on cross-section of a drawing for the sake of convenience, and an upper side, an upper portion, an upper surface, and the like are used to mean the opposite direction. However, this defines directions for convenience of description, and the scope of the claims is not particularly limited by the descriptions of the directions, and the concept of top/bottom may change at any time.

In the present disclosure, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” In addition, it may be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

In the present disclosure, thickness, width, length, depth, line width, spacing, pitch, and the like may be measured using a scanning microscope or an optical microscope based on cross-section obtained by polishing or cutting a PCB. The cut section may be a vertical cross-section or a horizontal cross-section, and each value may be measured based on the required cut section. For example, a width of an upper end and/or a lower end of a via may be measured from cross-section cut along a central axis of the via. At this time, if the value is not constant, the value may be determined as an average value of the values measured from five arbitrary points. Meanwhile, the minimum value may be determined as the smallest value measured in the corresponding layer or region.

The expression “an exemplary embodiment or one example” used in the present disclosure does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

The terms used herein are for the purpose of describing particular embodiments only and are not intended to limit the example embodiments. As used herein, the singular forms “a”, “an” and “the” are intended to include the plural forms as well, unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board comprising:
an insulating layer;
a through-hole including a first region penetrating through a portion of the insulating layer from an upper surface of the insulating layer and a second region penetrating through another portion of the insulating layer from a lower surface of the insulating layer; and
a metal via including a first metal layer disposed in a portion of the first region, a second metal layer disposed above the first metal layer and disposed in another portion of the first region, and a third metal layer disposed below the first metal layer and disposed in the second region,
wherein an upper surface of the first metal layer is located below the upper surface of the insulating layer.

2. The printed circuit board of claim 1, wherein the insulating layer includes a glass substrate.

3. The printed circuit board of claim 1, wherein the first metal layer has a boundary with each of the second and third metal layers.

4. The printed circuit board of claim 3, wherein an interface between the first and third metal layers is substantially the same as an interface between the first and second regions.

5. The printed circuit board of claim 1, wherein the first and second regions are arranged such that at least portions thereof overlaps each other on a plane, and are connected to each other based on a thickness direction.

6. The printed circuit board of claim 1, wherein, in a cross-section,
the first region has a tapered shape with an upper end having a width greater than a width of a lower end, and
the second region has a tapered shape tapered in a direction opposite to the first region, the second region having a lower portion having a width greater than a width of an upper end of the second region.

7. The printed circuit board of claim 6, wherein the width of the lower end of the first region is different from the width of the upper end of the second region.

8. The printed circuit board of claim 6, wherein the first region is deeper than the second region.

9. The printed circuit board of claim 1, wherein, in a cross section,
the first region has a rectangular shape with walls that are substantially vertical, and
the second region has a rectangular shape with walls that are substantially vertical.

10. The printed circuit board of claim 9, wherein a width of a lower end of the first region is different from a width of an upper end of the second region.

11. The printed circuit board of claim 9, wherein the first region is deeper than the second region.

12. The printed circuit board of claim 1, further comprising first and second metal interconnections respectively disposed on the upper and lower surfaces of the insulating layer and connected to each other through the metal via.

13. The printed circuit board of claim 12, wherein
the upper surface of the insulating layer is substantially coplanar with an upper surface of the second metal layer,
the lower surface of the insulating layer is substantially coplanar with a lower surface of the third metal layer,
the first metal interconnection includes: a first seed metal layer disposed on the upper surface of the insulating layer and the upper surface of the second metal layer and a first interconnection metal layer disposed on an upper surface of the first seed metal layer and having a thickness greater than that of the first seed metal layer, and
the second metal interconnection includes: a second seed metal layer disposed on the lower surface of the insulating layer and the lower surface of the third metal layer and a second interconnection metal layer disposed on a lower surface of the second seed metal layer and having a thickness greater than that of the second seed metal layer.

14. The printed circuit board of claim 12, wherein
the second metal layer extends to be disposed on the upper surface of the insulating layer,
the third metal layer extends to be disposed on the lower surface of the insulating layer,
the first metal interconnection includes the extended second metal layer, and
the second metal interconnection includes the extended third metal layer.

15. A method of manufacturing a printed circuit board, the method comprising:
forming a first through-hole in an insulating layer to penetrate through a portion of the insulating layer from an upper surface of the insulating layer;
forming a first metal layer filling a portion of the first through-hole;
forming a second through-hole in the insulating layer to penetrate through another portion of the insulating layer from a lower surface of the insulating layer and exposing a lower side of the first metal layer; and
forming second and third metal layers filling the first and second through-holes, respectively, on the upper and lower sides of the first metal layer.

16. The method of claim 15, wherein the insulating layer includes a glass substrate.

17. The method of claim 15, wherein the forming of the first metal layer includes:
filling a portion of the first through-hole with conductive paste, and
sintering the conductive paste.

18. The method of claim 15, wherein the forming of the second and third metal layers includes:
electroplating using the first metal layer as a seed layer to form plating layers on the upper and lower sides of the first metal layer, respectively, and
polishing the plating layers formed by the electroplating.

19. A printed circuit board comprising:
an insulating layer;
a through-hole including a first region penetrating through a portion of the insulating layer from an upper surface of the insulating layer and a second region penetrating through another portion of the insulating layer from a lower surface of the insulating layer to connect to the first region; and
a metal via including a first metal layer disposed in a portion of the first region and a third metal layer disposed below the first metal layer and disposed in the second region,
wherein in a cross-section, walls of the first region and the second region are inclined in different directions or have a step therebetween.

20. The printed circuit board of claim 19, wherein the insulating layer includes a glass substrate.

21. The printed circuit board of claim 19, wherein a boundary between the first and third metal layers is at a level corresponding to a level of an interface between the first and second regions.

22. The printed circuit board of claim 19, wherein, in the cross-section,
the first region has a tapered shape with an upper end having a width greater than a width of a lower end, and
the second region has a tapered shape tapered in a direction opposite to the first region.

23. The printed circuit board of claim 22, wherein the walls of the first region and the second region have the step therebetween.

24. The printed circuit board of claim 19, further comprising first and second metal interconnections respectively disposed on the upper and lower surfaces of the insulating layer and connected to each other through the metal via.

25. The printed circuit board of claim 24, wherein a material of the first metal interconnection is disposed in another portion of the first region to connect to the first metal layer.
